(19) United States
(12) Patent Application Publication
(10) Pub. No.: US 2024/0071882 A1
(43) Pub. Date: Feb. 29, 2024

(54) SEMICONDUCTOR PACKAGE

(71) Applicant: Samsung Electronics Co., Ltd., Suwon-si (KR)

(72) Inventors: Seongho SHIN, Suwon-si (KR); Sangkyu KIM, Suwon-si (KR); Juyoun CHOI, Suwon-si (KR)

(73) Assignee: Samsung Electronics Co., Ltd., Suwon-si (KR)

(21) Appl. No.: 18/366,098

(22) Filed: Aug. 7, 2023

(30) Foreign Application Priority Data
Aug. 29, 2022 (KR) 10-2022-0108653

(51) Int. Cl. H01L 23/498; H01L 23/00; H01L 23/373; H01L 25/065

(52) U.S. Cl. CPC H01L 23/49822; H01L 23/3735; H01L 23/49816; H01L 23/49838; H01L 24/16; H01L 24/32; H01L 25/0655; H01L 2224/16146; H01L 2224/16227; H01L 2224/32146; H01L 2924/1431; H01L 2924/1435

(57) ABSTRACT

A semiconductor package may include a package substrate and a silicon-free interposer. The silicon-free interposer may include a second core layer, first interposer through electrodes passing through the second core layer and connected to the first core through electrodes, and second interposer through electrodes passing through the second core layer and connected to the second core through electrodes. Diameters of the first core through electrodes may be different from diameters of the second core through electrodes, and diameters of the first interposer through electrodes may be different from diameters of the second interposer through electrodes.

### CROSS-REFERENCE TO RELATED APPLICATION

This application is based on and claims priority under 35 U.S.C. § 119 to Korean Patent Application No. 10-2022-0108653, filed on Aug. 29, 2022, in the Korean Intellectual Property Office, the disclosure of which is incorporated by reference herein in its entirety.

### BACKGROUND

Inventive concepts relate to a semiconductor package, and more particularly, to a semiconductor package including an interposer and a plurality of semiconductor chips mounted on the interposer.

Over the past decades, discovery of technologies, materials, and manufacturing processes has led to rapid development in computing power and wireless communication technology. Therefore, high-performance transistors may be directly implemented, and the speed of integration has doubled every 18 months according to Moore's law. Making a system light, thin, compact, and small and power efficient are enduring goals of semiconductor manufacturing. At this point in time when economic and physical process limits are reached, system packaging in which a system is implemented in a package is suggested as a valid solution.

Examples of system packaging technology include integration of a logic circuit and a memory circuit, sensor packaging, and heterogeneous integration of micro electro mechanical systems (MEMS) and a complementary metal-oxide-semiconductor (CMOS) logic circuit. System packaging enables achievement of high reliability, low power consumption, and low manufacturing cost as well as reduction in a form factor. On the other hand, because impedance matching of each element used for packaging, such as an interposer and a package substrate, affects completeness of a signal, the impedance matching is a core of a system packaging design.

### SUMMARY

Inventive concepts relate to a semiconductor package with improved reliability.

According to an embodiment of inventive concepts, a semiconductor package may include a package substrate; and a silicon-free interposer on the package substrate. The package substrate may include a first core layer, first core through electrodes passing through the first core layer, and second core through electrodes passing through the first core layer. The first core through electrodes may be configured to be applied with a high-speed signal. The second core through electrodes may be configured to be applied with power. The silicon-free interposer may include a second core layer, first interposer through electrodes passing through the second core layer, and second interposer through electrodes passing through the second core layer. The first interposer through electrodes may be connected to the first core through electrodes. The second interposer through electrodes may be connected to the second core through electrodes. Diameters of the first core through electrodes may be different from diameters of the second core through electrodes. Diameters of the first interposer through electrodes may be different from diameters of the second interposer through electrodes.

According to an embodiment of inventive concepts, a semiconductor package may include a package substrate; a silicon-free interposer on the package substrate; and a first semiconductor chip and a second semiconductor chip on the silicon-free interposer. The package substrate may include a first core layer, first core through electrodes passing through the first core layer, and second core through electrodes passing through the first core layer. The silicon-free interposer may include a second core layer, first interposer through electrodes passing through the second core layer, and second interposer through electrodes passing through the second core layer. The first interposer through electrodes may be connected to the first core through electrodes. The second interposer through electrodes may be connected to the second core through electrodes. The semiconductor package may be configured to output a high-speed signal from the first semiconductor chip and the second semiconductor chip to an outside region through the first interposer through electrodes and the first core through electrodes. Diameters of the first interposer through electrodes may be greater than diameters of the second interposer through electrodes.

According to an embodiment of inventive concepts, a semiconductor package may include a package substrate; and a silicon-free interposer on the package substrate. The package substrate may include a first core layer, first core through electrodes passing through the first core layer, and second core through electrodes passing through the first core layer. The first core layer may have a thickness in a range of 400 μm to 2,000 μm. Diameters of the first core through electrodes may be in a range of 75 μm to 190 μm. The first core through electrodes may be configured to be applied with a signal having a frequency of 1 GHz or more. Diameters of the second core through electrodes may be in a range of 75 μm to 125 μm. The silicon-free interposer may include a second core layer, first interposer through electrodes passing through the second core layer, and second interposer through electrodes passing through the second core layer. The second core layer may have a thickness in a range of 100 μm to 400 μm. The first interposer through electrodes may be connected to the first core through electrodes. Diameters of the first interposer through electrodes may be in a range of 30 μm to 80 μm. The second interposer through electrodes may be connected to the second core through electrodes. Diameters of the second interposer through electrodes may be in a range of 60 μm to 80 μm. The diameters of the first core through electrodes may be greater than the diameters of the second core through electrodes. The diameters of the first interposer through electrodes may be less than the diameters of the second interposer through electrodes.

### BRIEF DESCRIPTION OF THE DRAWINGS

Embodiments will be more clearly understood from the following detailed description taken in conjunction with the accompanying drawings in which:

FIG. 1A is a cross-sectional view illustrating a semiconductor package according to an embodiment of inventive concepts;

FIG. 1B is a cross-sectional view taken along the line 1B-1B′ of FIG. 1A;

FIG. 1C is a cross-sectional view taken along the line 1C-1C′ of FIG. 1A;

FIG. 2 is a cross-sectional view illustrating a semiconductor package according to another embodiment;

FIG. 3 is a cross-sectional view illustrating a semiconductor package according to another embodiment;

FIG. 4 is a cross-sectional view illustrating a semiconductor package according to another embodiment; and

FIG. 5 is a cross-sectional view illustrating a semiconductor package according to another embodiment.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments of inventive concepts will be described in detail with reference to the accompanying drawings. Like reference numerals refer to like elements throughout and description thereof will not be given.

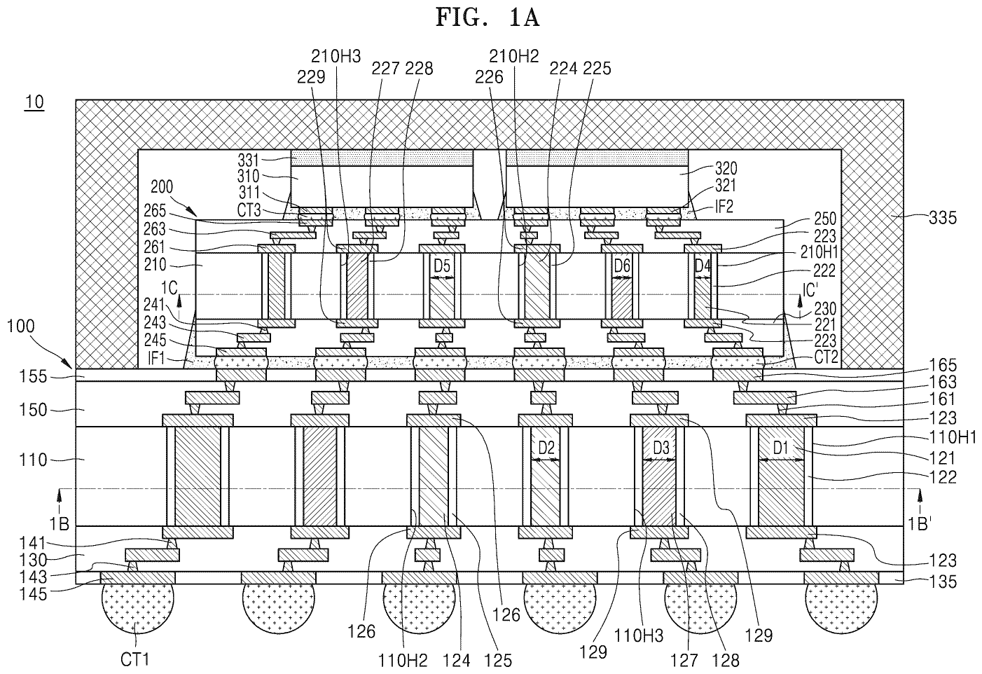

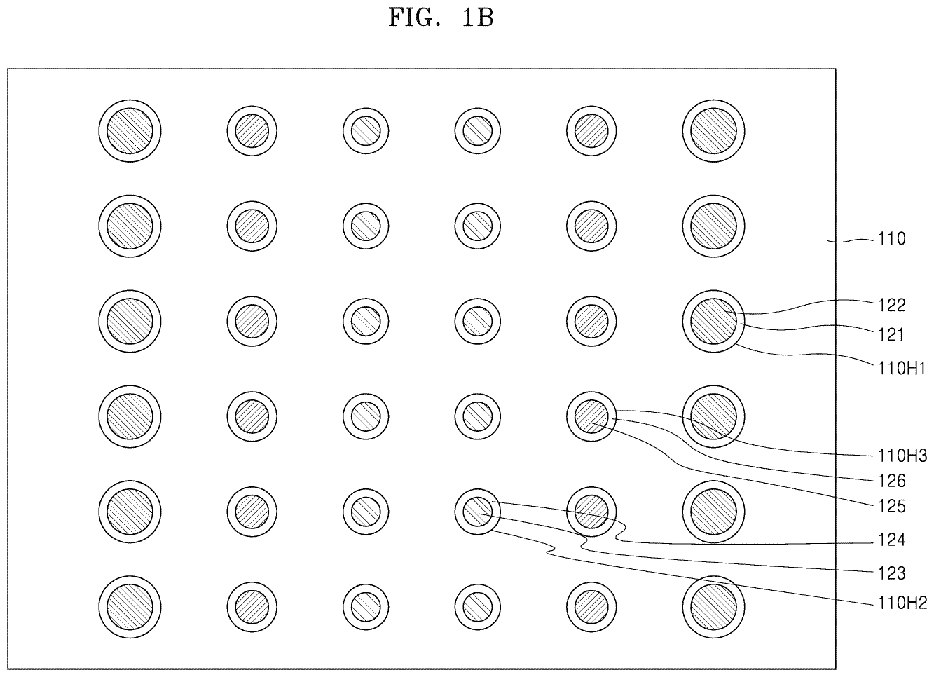

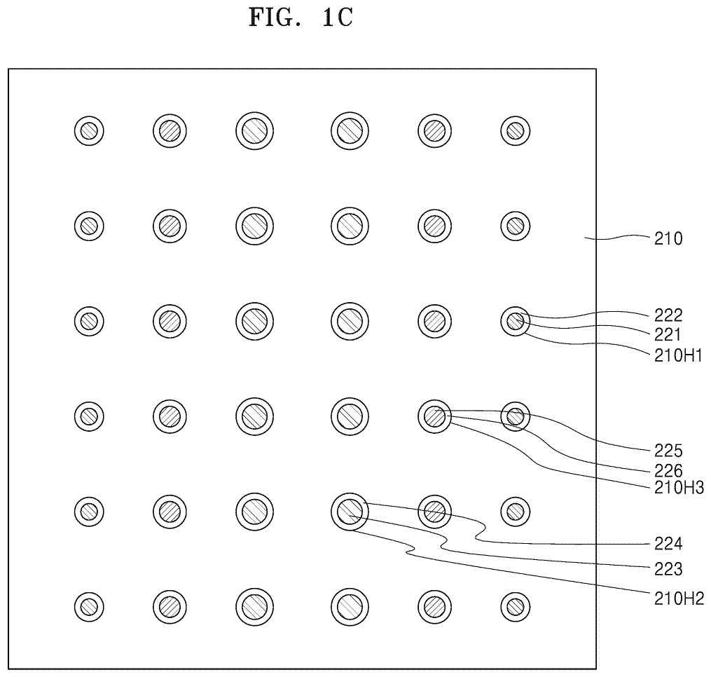

FIG. 1A is a cross-sectional view illustrating a semiconductor package 10 according to an embodiment of inventive concepts.

FIG. 1B is a cross-sectional view taken along the line 1B-1B′ of FIG. 1A.

FIG. 1C is a cross-sectional view taken along the line 1C-1C′ of FIG. 1A.

Referring to FIGS. 1A to 1C, the semiconductor package 10 may include a package substrate 100, a silicon-free interposer 200, a first semiconductor chip 310, a second semiconductor chip 320, thermal interface material (TIM) layers 331, and a heat dissipation device 335.

The package substrate 100 may include a first core layer 110, first core through electrodes 121, first passivation layers 122, first landing pads 123, second core through electrodes 124, second passivation layers 125, second landing pads 126, third core through electrodes 127, third passivation layers 128, third landing pads 129, a lower insulating layer 130, a lower protective layer 135, lower vias 141, lower traces 143, lower pads 145, an upper insulating layer 150, an upper protective layer 155, upper vias 161, upper traces 163, and upper pads 165.

According to embodiments, the package substrate 100 may include a multilayer printed circuit board (PCB). According to embodiments, the package substrate 100 may include a flexible PCB.

The first core layer 110 may include a resin or glass fiber. The resin may include one of a phenol resin, an epoxy resin, and polyimide. In some embodiments, the first core layer 110 may include at least one selected from flame retardant 4 (FR4), tetrafunctional epoxy, polyphenylene ether, epoxy/polyphenylene oxide, bismaleimide triazine (BT), thermount, cyanate ester, polyimide, prepreg, an Ajinomoto build-up film (ABF) of Ajinomoto Co., Inc., and liquid crystal polymer. However, inventive concepts are not limited thereto. For example, the first core layer 110 may include silicon oxide, silicon oxynitride, silicon nitride, or a combination thereof. Glass fiber that may be included in the first core layer 110 as one of the reinforcing materials may be obtained by twisting hundreds of strands of glass filaments each having a diameter of about 5 μm to about 15 μm to form a fiber bundle, and then weaving fiber bundles. The glass filament may include an ore processed product including silica as a main component. Glass fiber may have high heat resistance, mechanical strength, and electrical insulation.

The first core layer 110 may include first to third holes 110H1, 110H2, and 110H3. The first to third holes 110H1, 110H2, and 110H3 may pass through the first core layer 110. A diameter of each of the first holes 110H1 may be different from that of each of the second and third holes 110H2 and 110H3. The diameter of each of the first holes 110H1 may be greater than that of each of the second and third holes 110H2 and 110H3.

The first core through electrodes 121, the second core through electrodes 124, and the third core through electrodes 127 may pass through the first core layer 110 in a vertical direction. Here, the vertical direction is substantially perpendicular to a top surface of the package substrate 100, and a horizontal direction is parallel to the top surface of the package substrate 100.

The first core through electrodes 121 may be arranged in the first holes 110H1, respectively. The second core through electrodes 124 may be arranged in the second holes 110H2, respectively. The third core through electrodes 127 may be arranged in the third holes 110H3, respectively.

According to embodiments, the first core through electrodes 121, the second core through electrodes 124, and the third core through electrodes 127 may be cylindrical. According to embodiments, the first core through electrodes 121, the second core through electrodes 124, and the third core through electrodes 127 may extend in the vertical direction. According to embodiments, the first core through electrodes 121, the second core through electrodes 124, and the third core through electrodes 127 may extend from a top surface of the first core layer 110 to a bottom surface of the first core layer 110.

According to embodiments, a first diameter D1 of each of the first core through electrodes 121 may be different from a second diameter D2 of each of the second core through electrodes 124 and a third diameter D3 of each of the third core through electrodes 127. According to embodiments, the first diameter D1 of each of the first core through electrodes 121 may be greater than the second diameter D2 of each of the second core through electrodes 124. According to embodiments, the first diameter D1 of each of the first core through electrodes 121 may be greater than the third diameter D3 of each of the third core through electrodes 127.

According to embodiments, the first diameter D1 of each of the first core through electrodes 121 may be 1.5 times the second diameter D2 of each of the second core through electrodes 124 or less. According to embodiments, the first diameter D1 of each of the first core through electrodes 121 may be 1.5 times the third diameter D3 of each of the third core through electrodes 127 or less.

According to embodiments, the first diameter D1 of each of the first core through electrodes 121 may be in a range of about 75 μm to about 190 μm. According to embodiments, the second diameter D2 of each of the second core through electrodes 124 may be in a range of about 75 μm to about 125 μm. According to embodiments, the third diameter D3 of each of the third core through electrodes 127 may be in a range of about 75 μm to about 125 μm.

According to embodiments, each of the first core through electrodes 121, the second core through electrodes 124, and the third core through electrodes 127 may have inductance. The inductance of each of the first core through electrodes 121, the second core through electrodes 124, and the third core through electrodes 127 may be determined based on a physical shape thereof. According to embodiments, a first inductance of each of the first core through electrodes 121 may be different from a second inductance of each of the second core through electrodes 124 and third inductance of each of the third core through electrodes 127. According to embodiments, the first inductance of each of the first core through electrodes 121 may be less than the second inductance of each of the second core through electrodes 124 and the third inductance of each of the third core through electrodes 127.

According to embodiments, the first core through electrodes 121, the second core through electrodes 124, and the third core through electrodes 127 may have different functions. According to embodiments, different kinds of signals may be applied to the first core through electrodes 121, the second core through electrodes 124, and the third core through electrodes 127, respectively.

According to embodiments, a high-speed signal may be applied to the first core through electrodes 121. The high-speed signal introduced from the outside through external connection terminals CT1 may be transmitted to first and second semiconductor chips 310 and 320 through the first core through electrodes 121. The high-speed signal from the first and second semiconductor chips 310 and 320 may be output to the external connection terminals CT1 through the first core through electrodes 121. Here, the high-speed signal may have a frequency of about 1 GHz or more (e.g., 1 GHz to 5 GHz, or more).

When a thickness of the first core layer 110 is in a range of about 400 μm to about 2,000 μm, in order to reduce return loss of the high-speed signal to and/or from the first and second semiconductor chips 310 and 320, the inductance of each of the first core through electrodes 121, which corresponds to the high-speed signal, must be reduced. Here, the return loss is signal loss caused by transmission of signals output from the first and second semiconductor chips 310 and 320 back to the first and second semiconductor chips 310 and 320. According to embodiments, a thickness of each of the first core through electrodes 121 is made greater than that of each of the other core through electrodes (for example, the second and third core through electrodes 124 and 127) to reduce the return loss of the high-speed signal and to achieve impedance matching of the package substrate 100.

According to embodiments, ground potential or power potential may be applied to the second core through electrodes 124. According to embodiments, a low-speed signal may be applied to the third core through electrodes 127. Here, the low-speed signal may have a frequency less than about 1 GHz.

The first core through electrodes 121, the second core through electrodes 124, and the third core through electrodes 127 may include the same material. The first core through electrodes 121, the second core through electrodes 124, and the third core through electrodes 127 may include a conductive material. The first core through electrodes 121, the second core through electrodes 124, and the third core through electrodes 127 may include, for example, at least one selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), and graphene or an alloy of the metals.

In addition, the first landing pads 123, the second landing pads 126, the third landing pads 129, the lower vias 141, the lower traces 143, the lower pads 145, the upper vias 161, the upper traces 163, and the upper pads 165 to be described later may also include one of the materials described in relation to the first to third core through electrodes 121, 124, and 127.

Each of the first passivation layers 122 may be between each of the first core through electrodes 121 and the first core layer 110. Each of the first passivation layers 122 may contact one of the first core through electrodes 121. Each of the first passivation layers 122 may surround one of the first core through electrodes 121. Each of the first passivation layers 122 may have a uniform thickness. Each of the first passivation layers 122 may have a ring-shaped cross section. Here, a thickness of each of the first passivation layers 122 may be a difference between an outer radius and an inner radius of the ring-shaped cross-section. A thickness of each of the second and third passivation layers 125 and 128 and first to third conductive barriers 222, 225, and 228, which will be described later, may also be defined in a similar method to the thickness of each of the first passivation layers 122.

Each of the second passivation layers 125 may be between each of the second core through electrodes 124 and the first core layer 110. Each of the second passivation layers 125 may contact one of the second core through electrodes 124. Each of the second passivation layers 125 may surround one of the second core through electrodes 124. Each of the second passivation layers 125 may have a uniform thickness. Each of the second passivation layers 125 may have a ring-shaped cross-section. Here, a thickness of each of the second passivation layers 125 may be a difference between an outer radius and an inner radius of the ring-shaped cross-section.

Each of the third passivation layers 128 may be between each of the third core through electrodes 127 and the first core layer 110. Each of the third passivation layers 128 may contact one of the third core through electrodes 127. Each of the third passivation layers 128 may surround one of the third core through electrodes 127. Each of the third passivation layers 128 may have a uniform thickness. Each of the third passivation layers 128 may have a ring-shaped cross-section. Here, a thickness of each of the third passivation layers 128 may be a difference between an outer radius and an inner radius of the ring-shaped cross-section.

According to embodiments, the first to third passivation layers 122, 125, and 128 may have substantially the same thickness. According to embodiments, the inner radius of each of the first passivation layers 122 may be different from that of each of the second and third passivation layers 125 and 128. According to embodiments, the inner radius of each of the first passivation layers 122 may be greater than that of each of the second and third passivation layers 125 and 128. According to embodiments, the outer radius of each of the first passivation layers 122 may be different from that of each of the second and third passivation layers 125 and 128. According to embodiments, the outer radius of each of the first passivation layers 122 may be greater than that of each of the second and third passivation layers 125 and 128.

The first to third landing pads 123, 126, and 129 may be arranged on the top and bottom surfaces of the first core layer 110. Each two of the first landing pads 123 may be arranged on top and bottom surfaces of each of the first core through electrodes 121. Each two of the second landing pads 126 may be arranged on top and bottom surfaces of each of the second core through electrodes 124. Each two of the third landing pads 129 may be arranged on top and bottom surfaces of each of the third core through electrodes 127.

According to embodiments, a width of each of the first landing pads 123 may be different from that of each of the second landing pads 126 and that of each of the third landing pads 129. According to embodiments, the width of each of the first landing pads 123 may be greater than that of each of the second landing pads 126. According to embodiments, the width of each of the first landing pads 123 may be greater than that of each of the third landing pads 129.

The lower insulating layer 130 may be arranged on the bottom surface of the first core layer 110. The lower insulating layer 130 may include, for example, a dielectric material, such as prepreg.

The lower vias 141 and the lower traces 143 may be arranged in the lower insulating layer 130. The lower vias 141 and the lower traces 143 may be connected to the first to third landing pads 123, 126, and 129 and the lower pads 145. The lower vias 141 and the lower traces 143 may be embedded in the lower insulating layer 130. The lower traces 143 may extend in the horizontal direction. The lower vias 141 may extend in the vertical direction.

The lower vias 141 and the lower traces 143 may include a conductive material. The lower vias 141 and the lower traces 143 may provide an electrical path for transmitting signals and power.

According to embodiments, the lower vias 141 and the lower traces 143 may be formed by a single damascene process. However, inventive concepts are not limited thereto. The lower vias 141 and the lower traces 143 may be formed by a dual damascene process. In this case, the lower vias 141 in one layer and the lower traces 143 in one layer may be integrated to form continuous features.

The lower protective layer 135 may be arranged on the lower insulating layer 130. The lower protective layer 135 may include an insulating coating film. The lower protective layer 135 may include, for example, solder resist. The lower protective layer 135 may include side walls defining openings exposing parts of top surfaces of the lower pads 145. The lower protective layer 135 may protect the lower pads 145 and may limit and/or prevent a bridge from occurring between each two of the lower pads 145.

The upper insulating layer 150 may be arranged on the bottom surface of the first core layer 110. The upper insulating layer 150 may include, for example, a dielectric material, such as prepreg.

The upper vias 161 and the upper traces 163 may be arranged in the upper insulating layer 150. The upper vias 161 and the upper traces 163 may be connected to the first to third landing pads 123, 126, and 129 and the upper pads 165. The upper vias 161 and the upper traces 163 may be embedded in the upper insulating layer 150. The upper traces 163 may extend in the horizontal direction. The lower vias 141 may extend in the vertical direction.

The upper vias 161 and the upper traces 163 may include a conductive material. The upper vias 161 and the upper traces 163 may provide an electrical path for transmitting signals and power.

According to embodiments, the upper vias 161 and the upper traces 163 may be formed by a single damascene process. However, inventive concepts are not limited thereto. The upper vias 161 and the upper traces 163 may be formed by a dual damascene process.

The upper protective layer 155 may be arranged on the upper insulating layer 150. The upper protective layer 155 may include an insulating coating film. The upper protective layer 155 may include, for example, solder resist. The upper protective layer 155 may include side walls defining openings exposing parts of top surfaces of the upper pads 165. The upper protective layer 155 may protect the upper pads 165 and may limit and/or prevent a bridge from occurring between each two of the upper pads 165.

The lower pads 145 may be arranged on the lower insulating layer 130 to be apart from one another in the horizontal direction. For example, the lower pads 145 may be arranged on a bottom surface of the lower protective layer 135 to form an array. In a plan view, each of the lower pads 145 may be, for example, a polygon, such as a quadrangle or a hexagon. Alternatively, the lower pads 145 may be circular or elliptical in a plan view.

According to embodiments, the lower pads 145 may have a uniform thickness. Each of the lower pads 145 may have a top surface contacting the first lower insulating layer 130 and each of the lower vias 141 and a bottom surface opposite to the top surface. The top and bottom surfaces of each of the lower pads 145 may be planar.

Description of the shape and arrangement of each of the lower pads 145 may be similarly applied to the other pads (for example, the upper pads 165, the first to third landing pads 123, 126, and 129, first to third interposer landing pads 223, 226, and 229, lower pads 245, upper pads 265, and first and second chip pads 311 and 321).

The external connection terminals CT1 configured to electrically connect an external device to the semiconductor package 10 may be connected onto the lower pads 145. Board-interposer connection terminals CT2 may be respectively provided on the upper pads 165. The external connection terminals CT1 and the board-interposer connection terminals CT2 may include, for example, a solder material.

The external connection terminals CT1 may be larger than the board-interposer connection terminals CT2. The board-interposer connection terminals CT2 may be larger than chip connection terminals CT3 to be described later. The package substrate 100 may be connected to the silicon-free interposer 200 through the board-interposer connection terminals CT2.

The silicon-free interposer 200 may be arranged on the package substrate 100. The silicon-free interposer 200 may resolve mismatch between a footprint of the package substrate 100 and a footprint between the first and second semiconductor chips 310 and 320. For example, the first and second chip pads 311 and 321 of the first and second semiconductor chips 310 and 320 may be smaller than the upper pads 165 of the package substrate 100, and the silicon-free interposer 200 between the first and second semiconductor chips 310 and 320 and the package substrate 100 may mediate a connection between the first and second semiconductor chips 310 and 320 and the package substrate 100.

A first insulating filler IF1 may be between the package substrate 100 and the silicon-free interposer 200. The first insulating filler IF1 may include an epoxy molding compound (EMC) or a non-conductive film (NCF). The first insulating filler IF1 may cover the upper pads 165, the board-interposer connection terminals CT2, and the lower pads 245. The first insulating filler IF1 may protect the upper pads 165, the board-interposer connection terminals CT2, and the lower pads 245. The first insulating filler IF1 may ensure fixation between the package substrate 100 and the silicon-free interposer 200.

The silicon-free interposer 200 may include a second core layer 210, first interposer through electrodes 221, the first conductive barriers 222, the first interposer landing pads 223, second interposer through electrodes 224, the second conductive barriers 225, the second interposer landing pads 226, third interposer through electrodes 227, the third conductive barriers 228, the third interposer landing pads 229, a lower insulating layer 230, lower vias 241, lower redistribution patterns 243, the lower pads 245, an upper insulating layer 250, upper vias 261, upper redistribution patterns 263, and the upper pads 265.

According to embodiments, the second core layer 210 may include one of the materials described in relation to the first core layer 110, except for a semiconductor material, such as silicon.

The second core layer 210 may include first to third holes 210H1, 210H2, and 210H3. The first to third holes 210H1, 210H2, and 210H3 may pass through the second core layer 210. A diameter of each of the first holes 210H1 may be different from that of each of the second and third holes 210H2 and 210H3. The diameter of each of the first holes 210H1 may be less than that of each of the second and third holes 210H2 and 210H3.

The first interposer through electrodes 221, the second interposer through electrodes 224, and the third interposer through electrodes 227 may pass through the second core layer 210 in the vertical direction. Here, the vertical direction is substantially perpendicular to a top surface of the second core layer 210, and the horizontal direction is parallel to the top surface of the second core layer 210.

The first interposer through electrodes 221 may be arranged in the first holes 210H1, respectively. The second interposer through electrodes 224 may be arranged in the second holes 210H2, respectively. The third interposer through electrodes 227 may be arranged in the third holes 210H3, respectively.

According to embodiments, the first interposer through electrodes 221, the second interposer through electrodes 224, and the third interposer through electrodes 227 may be cylindrical. According to embodiments, the first interposer through electrodes 221, the second interposer through electrodes 224, and the third interposer through electrodes 227 may extend in the vertical direction. According to embodiments, the first interposer through electrodes 221, the second interposer through electrodes 224, and the third interposer through electrodes 227 may extend from a top surface of the second core layer 210 to a bottom surface of the second core layer 210.

According to embodiments, a fourth diameter D4 of each of the first interposer through electrodes 221 may be different from a fifth diameter D5 of each of the second interposer through electrodes 224 and a sixth diameter D6 of each of the third interposer through electrodes 227. According to embodiments, the fourth diameter D4 of each of the first interposer through electrodes 221 may be less than the fifth diameter D5 of each of the second interposer through electrodes 224. According to embodiments, the fourth diameter D4 of each of the first interposer through electrodes 221 may be less than the sixth diameter D6 of each of the third interposer through electrodes 227.

According to embodiments, the fourth diameter D4 of each of the first interposer through electrodes 221 may be 0.5 times the fifth diameter D5 of each of the second interposer through electrodes 224 or more (e.g., greater than or equal to 0.5 and less than 1.0). According to embodiments, the fourth diameter D4 of each of the first interposer through electrodes 221 may be 0.5 times the sixth diameter D6 of each of the third interposer through electrodes 227 or more (e.g., greater than or equal to 0.5 and less than 1.0).

According to embodiments, the fourth diameter D4 of each of the first interposer through electrodes 221 may be in a range of about 30 μm to about 80 μm. According to embodiments, the fifth diameter D5 of each of the second interposer through electrodes 224 may be in a range of about 60 μm to about 80 μm. According to embodiments, the sixth diameter D6 of each of the third interposer through electrodes 227 may be in a range of about 60 μm to about 80 μm.

According to embodiments, each of the first interposer through electrodes 221, the second interposer through electrodes 224, and the third interposer through electrodes 227 may have inductance. The inductance of each of the first interposer through electrodes 221, the second interposer through electrodes 224, and the third interposer through electrodes 227 may be determined based on a physical shape thereof. According to embodiments, a fourth inductance of each of the first interposer through electrodes 221 may be different from a fifth inductance of each of the second interposer through electrodes 224 and a sixth inductance of each of the third interposer through electrodes 227. According to embodiments, a first inductance of each of the first interposer through electrodes 221 may be greater than the fifth inductance of each of the second interposer through electrodes 224 and the sixth inductance of each of the third interposer through electrodes 227.

When a thickness of the second core layer 210 is in a range of about 100 μm to about 400 μm, in order to reduce return loss of the high-speed signal to and/or from the first and second semiconductor chips 310 and 320, the inductance of each of the first interposer through electrodes 221, which corresponds to the high-speed signal, must be increased. According to embodiments, a thickness of each of the first interposer through electrodes 221 is made greater than that of each of the other interposer through electrodes (for example, the second and third interposer through electrodes 224 and 227) to reduce the return loss of the high-speed signal and to achieve impedance matching of the silicon-free interposer 200.

According to embodiments, the first interposer through electrodes 221 may be connected to the first core through electrodes 121 through the first interposer landing pads 223, the lower vias 241, the lower traces 243, the lower pads 245, the board-interposer connection terminals CT2, the upper pads 165, the upper traces 163, the upper vias 161, and the first landing pads 123.

According to embodiments, the second interposer through electrodes 224 may be connected to the second core through electrodes 124 through the second interposer landing pads 226, the lower vias 241, the lower traces 243, the lower pads 245, the board-interposer connection terminals CT2, the upper pads 165, the upper traces 163, the upper vias 161, and the second landing pads 126.

According to embodiments, the third interposer through electrodes 227 may be connected to the third core through electrodes 127 through the third interposer landing pads 229, the lower vias 241, the lower traces 243, the lower pads 245, the board-interposer connection terminals CT2, the upper pads 165, the upper traces 163, the upper vias 161, and the third landing pads 129.

According to embodiments, the first interposer through electrodes 221, the second interposer through electrodes 224, and the third interposer through electrodes 227 may have different functions. According to embodiments, different kinds of signals may be applied to the first interposer through electrodes 221, the second interposer through electrodes 224, and the third interposer through electrodes 227.

According to embodiments, a high-speed signal may be applied to the first interposer through electrodes 221. The high-speed signal introduced from the outside through external connection terminals CT1 may be transmitted to the first and second semiconductor chips 310 and 320 through the first interposer through electrodes 221. The high-speed signal from the first and second semiconductor chips 310 and 320 may be transmitted to the first core through electrodes 121 through the first interposer through electrodes 221.

According to embodiments, ground potential or power potential may be applied to the second interposer through electrodes 224. According to embodiments, a low-speed signal may be applied to the third interposer through electrodes 227.

The first interposer through electrodes 221, the first interposer landing pads 223, the second interposer through electrodes 224, the second interposer landing pads 226, the third interposer through electrodes 227, the third interposer landing pads 229, the lower vias 241, the lower redistribution patterns 243, the lower pads 245, the upper vias 261, the upper redistribution patterns 263, and the upper pads 265 may include one of the materials described in relation to the first to third core through electrodes 121, 124, and 127.

Each of the first conductive barriers 222 may be between one of the first interposer through electrodes 221 and the second core layer 210. Each of the first conductive barriers 222 may contact one of the first interposer through electrodes 221. Each of the first conductive barriers 222 may surround one of the first interposer through electrodes 221. Each of the first conductive barriers 222 may have a uniform thickness. Each of the first conductive barriers 222 may have a ring-shaped cross-section.

Each of the second conductive barriers 225 may be between each of the second interposer through electrodes 224 and the second core layer 210. Each of the second conductive barriers 225 may contact one of the second interposer through electrodes 224. Each of the second conductive barriers 225 may surround one of the second interposer through electrodes 224. Each of the second conductive barriers 225 may have a uniform thickness. Each of the second conductive barriers 225 may have a ring-shaped cross-section.

Each of the third conductive barriers 228 may be between one of the third interposer through electrodes 227 and the second core layer 210. Each of the third conductive barriers 228 may contact one of the third interposer through electrodes 227. Each of the third conductive barriers 228 may surround one of the third interposer through electrodes 227. Each of the third conductive barriers 228 may have a uniform thickness. Each of the third conductive barriers 228 may have a ring-shaped cross-section.

According to embodiments, the first to third conductive barriers 222, 225, and 228 may have substantially the same thickness. According to embodiments, an inner radius of each of the first conductive barriers 222 may be different from that of each of the second and third conductive barriers 225 and 228. According to embodiments, the inner radius of each of the first conductive barriers 222 may be greater than that of each of the second and third conductive barriers 225 and 228. According to embodiments, the outer radius of each of the first conductive barriers 222 may be different from that of each of the second and third conductive barriers 225 and 228. According to embodiments, the outer radius of each of the first conductive barriers 222 may be greater than that of each of the second and third conductive barriers 225 and 228.

The first to third conductive barriers 222, 225, and 228 may include one material selected from Ti, titanium nitride (TiN), tantalum (Ta), tantalum nitride (TaN), ruthenium (Ru), Co, manganese (Mn), tungsten nitride (WN), Ni, and nickel boride (NiB). A via insulating layer may be further between the second core layer 210 and each of the first to third conductive barriers 222, 225, and 228. The via insulating layer may include an oxide layer, a nitride layer, a carbonaceous layer, polymer, or a combination thereof.

The first to third interposer landing pads 223, 226, and 229 may be arranged on the top and bottom surfaces of the second core layer 210. Each two of the first interposer landing pads 223 may be arranged on top and bottom surfaces of each of the first interposer through electrodes 221. Each two of the second interposer landing pads 226 may be arranged on top and bottom surfaces of each of the second interposer through electrodes 224. Each two of the third interposer landing pads 229 may be arranged on top and bottom surfaces of each of the third interposer through electrodes 227.

According to embodiments, a width of each of the first interposer landing pads 223 may be different from that of each of the second interposer landing pads 226 and that of each of the third interposer landing pads 229. According to embodiments, the width of each of the first interposer landing pads 223 may be less than that of each of the second interposer landing pads 226. According to embodiments, the width of each of the first interposer landing pads 223 may be less than that of each of the third interposer landing pads 229.

The lower insulating layer 230 may be arranged on the bottom surface of the second core layer 210. The lower insulating layer 230 may include, for example, an organic insulating material, such as photoimageable dielectric (PID) polyimide (PI) or polybenzoxazole (PBO).

The lower vias 241 and the lower redistribution patterns 243 may be arranged in the lower insulating layer 230. The lower vias 241 and the lower redistribution patterns 243 may be connected to the first to third interposer landing pads 223, 226, and 229 and the lower pads 245. The lower vias 241 and the lower redistribution patterns 243 may be embedded in the lower insulating layer 230. The lower redistribution patterns 243 may extend in the horizontal direction. The lower vias 241 may extend in the vertical direction.

The lower vias 241 and the lower redistribution patterns 243 may include a conductive material. The lower vias 241 and the lower redistribution patterns 243 may provide an electrical path for transmitting signals and power.

According to embodiments, the lower vias 241 and the lower redistribution patterns 243 may be formed by a single damascene process. However, inventive concepts are not limited thereto. The lower vias 241 and the lower redistribution patterns 243 may be formed by a dual damascene process.

The upper insulating layer 250 may be arranged on the bottom surface of the second core layer 210. The upper insulating layer 250 may include the materials described above in relation to the lower insulating layer 230.

The upper vias 261 and the upper redistribution patterns 263 may be arranged in the upper insulating layer 250. The upper vias 261 and the upper redistribution patterns 263 may be connected to the first to third interposer landing pads 223, 226, and 229 and the upper pads 265. The upper vias 261 and the upper redistribution patterns 263 may be embedded in the upper insulating layer 250. The upper redistribution patterns 263 may extend in the horizontal direction. The lower vias 241 may extend in the vertical direction.

The upper vias 261 and the upper redistribution patterns 263 may include a conductive material. The upper vias 261 and the upper redistribution patterns 263 may provide an electrical path for transmitting signals and power.

According to embodiments, the upper vias 261 and the upper redistribution patterns 263 may be formed by a single damascene process. However, inventive concepts are not limited thereto. The upper vias 261 and the upper redistribution patterns 263 may be formed by a dual damascene process.

The first and second semiconductor chips 310 and 320 may be mounted on the silicon-free interposer 200. The first and second semiconductor chips 310 and 320 may be apart from each other in the horizontal direction. The first and second semiconductor chips 310 and 320 may be mounted on the silicon-free interposer 200 in a flip chip method. A bottom surface of the first semiconductor chip 310, on which the first chip pads 311 are formed, and a bottom surface of the second semiconductor chip 320, on which the second chip pads 321 are formed, may face the silicon-free interposer 200. The first and second chip pads 311 and 321 of the first and second semiconductor chips 310 and 320 may be electrically connected to upper redistribution patterns 263 through the chip connection terminals CT3. The first and second chip pads 311 and 321 of the first and second semiconductor chips 310 and 320 may include terminals for transmitting input/output data signals or terminals for power and/or ground.

Each of the first and second semiconductor chips 310 and 320 may include a semiconductor substrate and a semiconductor device layer. The semiconductor substrate may include an active surface and an inactive surface opposite to each other. The semiconductor substrate may include silicon, for example, crystalline silicon, polycrystalline silicon, or amorphous silicon. The semiconductor device layer may be formed on the active surface of the semiconductor substrate. Each of the first and second semiconductor chips 310 and 320 may include a bottom surface and a top surface opposite to each other. The bottom surface of each of the first and second semiconductor chips 310 and 320 may be adjacent to the active surface of the semiconductor substrate, and the top surface of each of the first and second semiconductor chips 310 and 320 may be adjacent to the inactive surface of the semiconductor substrate. The first chip pads 311 of the first semiconductor chip 310 may be arranged on the bottom surface of the first semiconductor chip 310, and the second chip pads 321 of the second semiconductor chip 320 may be arranged on the bottom surface of the second semiconductor chip 320. The first chip pads 311 of the first semiconductor chip 310 and the second chip pads 321 of the second semiconductor chip 320 may be electrically connected to individual devices of the semiconductor device layer through wiring structures (not shown) provided therein. The first and second semiconductor chips 310 and 320 may be electrically connected to the package substrate 100 through the silicon-free interposer 200.

For example, the first semiconductor chip 310 of the semiconductor package 10 may include a logic chip, and the second semiconductor chip 320 of the semiconductor package 10 may include a memory chip. According to embodiments, the second semiconductor chip 320 may include a volatile memory chip and/or a non-volatile memory chip. For example, the volatile memory chip may include dynamic random access memory (DRAM), static RAM (SRAM), thyristor RAM (TRAM), zero capacitor RAM (ZRAM), or twin transistor RAM (TTRAM). In addition, the non-volatile memory chip may include, for example, flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, or insulator resistance change memory.

In another example, the second semiconductor chip 320 may include a stacked semiconductor memory chip. The stacked semiconductor memory chip may be implemented based on a high bandwidth memory (HBM) or hybrid memory cube (HMC) standard.

The first semiconductor chip 310 may execute applications supported by the semiconductor package 10 by using the second semiconductor chip 320. For example, the first semiconductor chip 310 may include at least one of a central processing unit (CPU), an application processor (AP), a graphics processing unit (GPU), a neural processing unit (NPU), a tensor processing unit (TPU), a vision processing unit (VPU), an image signal processor (ISP), and a digital signal processor (DSP) to perform specialized operations.

The semiconductor package 10 may include a second insulating filler IF2 arranged between each of the first and second semiconductor chips 310 and 320 and the silicon-free interposer 200. The second insulating filler IF2 may include one of the materials described above in relation to the first insulating filler IF1.

The TIM layers 331 may be arranged on the first and second semiconductor chips 310 and 320. The TIM layers 331 may vertically overlap the first and second semiconductor chips 310 and 320. The TIM layers 331 may contact the first and second semiconductor chips 310 and 320.

The heat dissipation device 335 may cover the top surfaces of the first and second semiconductor chips 310 and 320. The heat dissipation device 335 may contact the TIM layers 331. The heat dissipation device 335 may include a heat dissipation plate, such as a heat slug or a heat sink. According to embodiments, the heat dissipation device 335 may be attached onto the top surface of the package substrate 100. According to embodiments, the heat dissipation device 335 may horizontally surround side walls of the silicon-free interposer 200 and the first and second semiconductor chips 310 and 320.

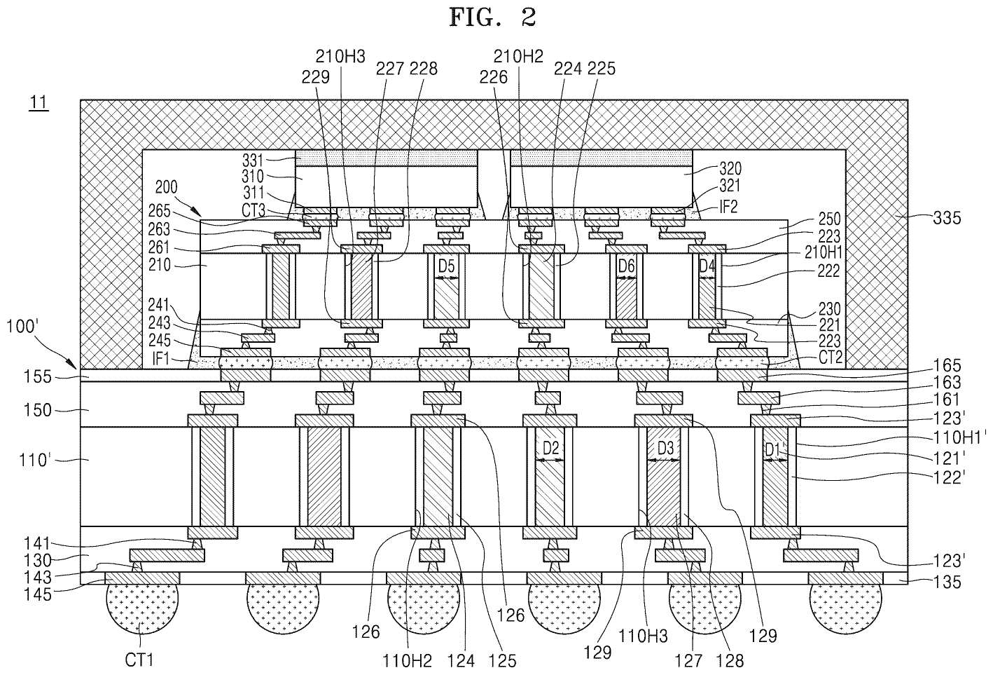

FIG. 2 is a cross-sectional view illustrating a semiconductor package 11 according to another embodiment.

Referring to FIG. 2, the semiconductor package 11 may include a package substrate 100′, a silicon-free interposer 200, a first semiconductor chip 310, a second semiconductor chip 320, TIM layers 331, and a heat dissipation device 335.

Because the silicon-free interposer 200, the first semiconductor chip 310, the second semiconductor chip 320, the TIM layers 331, and the heat dissipation device 335 are substantially the same as those described with reference to FIGS. 1A to 1C, description thereof will not be given.

The package substrate 100′ may include a first core layer 110′, first core through electrodes 121′, first passivation layers 122′, first landing pads 123′, second core through electrodes 124, second passivation layers 125, second landing pads 126, third core through electrodes 127, third passivation layers 128, third landing pads 129, a lower insulating layer 130, a lower protective layer 135, lower vias 141, lower traces 143, lower pads 145, an upper insulating layer 150, an upper protective layer 155, upper vias 161, upper traces 163, and upper pads 165.

The first core layer 110′ may include first holes 110H1′, second holes 110H2, and third holes 110H3. The first core through electrodes 121′ may be arranged in the first holes 110H1′. A diameter of each of the first holes 110H1′ may be different from that of each of the second holes 110H2. The diameter of each of the first holes 110H1′ may be different from that of each of the third holes 110H3. The diameter of each of the first holes 110H1′ may be less than that of each of the second holes 110H2. The diameter of each of the first holes 110H1′ may be less than that of each of the third holes 110H3.

According to embodiments, the first core through electrodes 121′ may be cylindrical. According to embodiments, the first core through electrodes 121′ may extend in the vertical direction. According to embodiments, the first core through electrodes 121′ may extend from a top surface of the first core layer 110′ to a bottom surface of the first core layer 110′.

According to embodiments, a first diameter D1′ of each of the first core through electrodes 121′ may be different from a second diameter D2 of each of the second core through electrodes 124 and a third diameter D3 of each of the third core through electrodes 127. According to embodiments, the first diameter D1′ of each of the first core through electrodes 121′ may be less than the second diameter D2 of each of the second core through electrodes 124. According to embodiments, the first diameter D1′ of each of the first core through electrodes 121′ may be less than the third diameter D3 of each of the third core through electrodes 127.

According to embodiments, the first diameter D1′ of each of the first core through electrodes 121′ may be 0.5 times the second diameter D2 of each of the second core through electrodes 124 or more (e.g., greater than or equal to 0.5 and less than 1.0). According to embodiments, the first diameter D1′ of each of the first core through electrodes 121′ may be 0.5 times the third diameter D3 of each of the third core through electrodes 127 or more (e.g., greater than or equal to 0.5 and less than 1.0). According to embodiments, the first diameter D1′ of each of the first core through electrodes 121′ may be in a range of about 35 μm to about 125 μm.

Each of the first passivation layers 122′ may be between each of the first core through electrodes 121′ and the first core layer 110′. Each of the first passivation layers 122′ may contact one of the first core through electrodes 121′. Each of the first passivation layers 122′ may surround one of the first core through electrodes 121′. Each of the first passivation layers 122′ may have a uniform thickness. Each of the first passivation layers 122′ may have a ring-shaped cross-section.

According to embodiments, the first core through electrodes 121′, the second core through electrodes 124, and the third core through electrodes 127 may have different functions. According to embodiments, different kinds of signals may be applied to the first core through electrodes 121′, the second core through electrodes 124, and the third core through electrodes 127, respectively.

According to embodiments, a high-speed signal may be applied to the first core through electrodes 121′. The high-speed signal introduced from the outside through external connection terminals CT1 may be transmitted to the first and second semiconductor chips 310 and 320 through the first core through electrodes 121′.

Each of the first passivation layers 122′ may be between each of the first core through electrodes 121′ and the first core layer 110′. Each of the first passivation layers 122′ may contact one of the first core through electrodes 121′. Each of the first passivation layers 122′ may surround one of the first core through electrodes 121′. Each of the first passivation layers 122′ may have a uniform thickness. Each of the first passivation layers 122′ may have a ring-shaped cross-section.

The first to third landing pads 123′, 126, and 129 may be arranged on the top and bottom surfaces of the first core layer 110′. Each two of the first landing pads 123′ may be arranged on top and bottom surfaces of each of the first core through electrodes 121′.

According to embodiments, a width of each of the first landing pads 123′ may be different from that of each of the second landing pads 126 and that of each of the third landing pads 129. According to embodiments, the width of each of the first landing pads 123′ may be less than that of each of the second landing pads 126. According to embodiments, the width of each of the first landing pads 123′ may be less than that of each of the third landing pads 129.

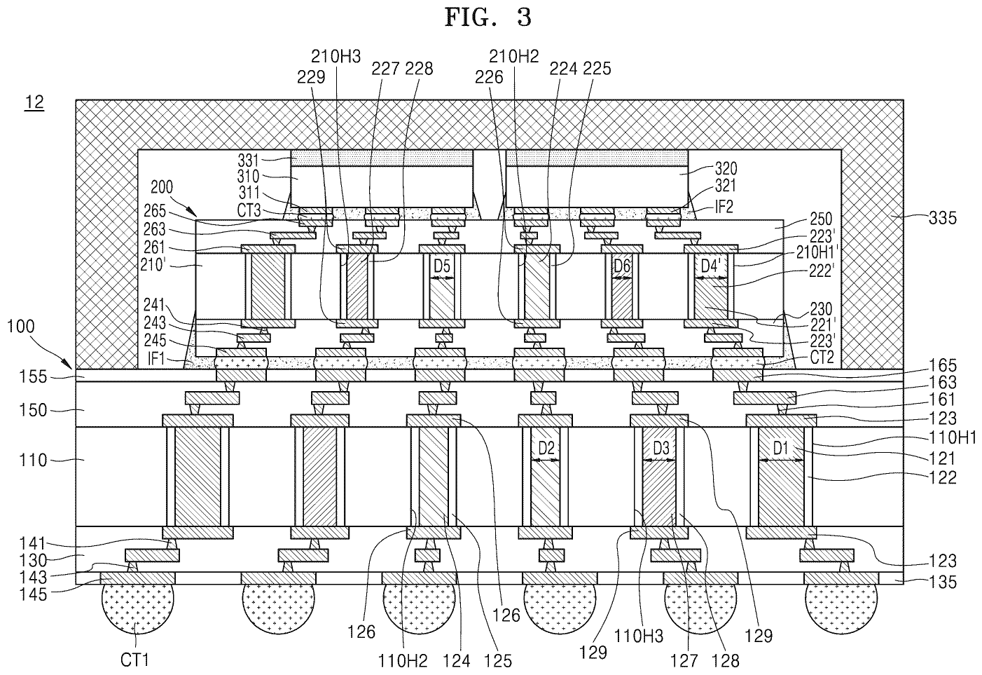

FIG. 3 is a cross-sectional view illustrating a semiconductor package 12 according to another embodiment.

Referring to FIG. 3, the semiconductor package 12 may include a package substrate 100, a silicon-free interposer 200′, a first semiconductor chip 310, a second semiconductor chip 320, TIM layers 331, and a heat dissipation device 335.

Because the package substrate 100, the first semiconductor chip 310, the second semiconductor chip 320, the TIM layers 331, and the heat dissipation device 335 are substantially the same as those described with reference to FIGS. 1A to 1C, description thereof will not be given.

According to embodiments, a second core layer 210′ may include one of the materials described in relation to a first core layer 110.

The second core layer 210′ may include first to third holes 210H1′, 210H2, and 210H3. The first to third holes 210H1′, 210H2, and 210H3 may pass through the second core layer 210′. A diameter of each of the first holes 210H1′ may be different from that of each of the second and third holes 210H2 and 210H3. The diameter of each of the first holes 210H1′ may be less than that of each of the second and third holes 210H2 and 210H3.

First interposer through electrodes 221′, second interposer through electrodes 224, and third interposer through electrodes 227 may pass through the second core layer 210′ in the vertical direction. Here, the vertical direction is substantially perpendicular to a top surface of the second core layer 210′, and the horizontal direction is parallel to the top surface of the second core layer 210′.

The first interposer through electrodes 221′ may be arranged in the first holes 210H1′, respectively. According to embodiments, the first interposer through electrodes 221′ may be cylindrical. According to embodiments, the first interposer through electrodes 221′ may extend in the vertical direction. According to embodiments, the first interposer through electrodes 221′ may extend from the top surface of the second core layer 210′ to a bottom surface of the second core layer 210′.

According to embodiments, a fourth diameter D4′ of each of the first interposer through electrodes 221′ may be different from a fifth diameter D5 of each of the second interposer through electrodes 224 and a sixth diameter D6 of each of the third interposer through electrodes 227. According to embodiments, the fourth diameter D4′ of each of the first interposer through electrodes 221′ may be greater than the fifth diameter D5 of each of the second interposer through electrodes 224. According to embodiments, the fourth diameter D4′ of each of the first interposer through electrodes 221′ may be greater than the sixth diameter D6 of each of the third interposer through electrodes 227.

According to embodiments, the fourth diameter D4′ of each of the first interposer through electrodes 221′ may be 0.5 times the fifth diameter D5 of each of the second interposer through electrodes 224 or less. According to embodiments, the fourth diameter D4′ of each of the first interposer through electrodes 221′ may be 1.5 times the sixth diameter D6 of each of the third interposer through electrodes 227 or less. According to embodiments, the fourth diameter D4′ of each of the first interposer through electrodes 221′ may be in a range of about 60 μm to about 120 μm.

According to embodiments, the first interposer through electrodes 221′, the second interposer through electrodes 224, and the third interposer through electrodes 227 may have different functions. According to embodiments, different kinds of signals may be applied to the first interposer through electrodes 221′, the second interposer through electrodes 224, and the third interposer through electrodes 227.

According to embodiments, a high-speed signal may be applied to the first interposer through electrodes 221′. The high-speed signal introduced from the outside through external connection terminals CT1 may be transmitted to the first and second semiconductor chips 310 and 320 through the first interposer through electrodes 221′. The high-speed signal from the first and second semiconductor chips 310 and 320 may be transmitted to first core through electrodes 121 through the first interposer through electrodes 221′.

Each of first conductive barriers 222′ may be between each of first interposer through electrodes 221′ and the second core layer 210′. Each of the first conductive barriers 222′ may contact each of the first interposer through electrodes 221′. Each of the first conductive barriers 222′ may surround each of the first interposer through electrodes 221′. Each of the first conductive barriers 222′ may have a uniform thickness. Each of the first conductive barriers 222′ may have a ring-shaped cross-section.

First to third interposer landing pads 223′, 226, and 229 may be arranged on the top and bottom surfaces of the second core layer 210′. Each two of the first interposer landing pads 223′ may be arranged on top and bottom surfaces of each of the first interposer through electrodes 221′.

According to embodiments, a width of each of the first interposer landing pads 223′ may be different from that of each of the second interposer landing pads 226 and that of each of the third interposer landing pads 229. According to embodiments, the width of each of the first interposer landing pads 223′ may be greater than that of each of the second interposer landing pads 226. According to embodiments, the width of each of the first interposer landing pads 223′ may be greater than that of each of the third interposer landing pads 229.

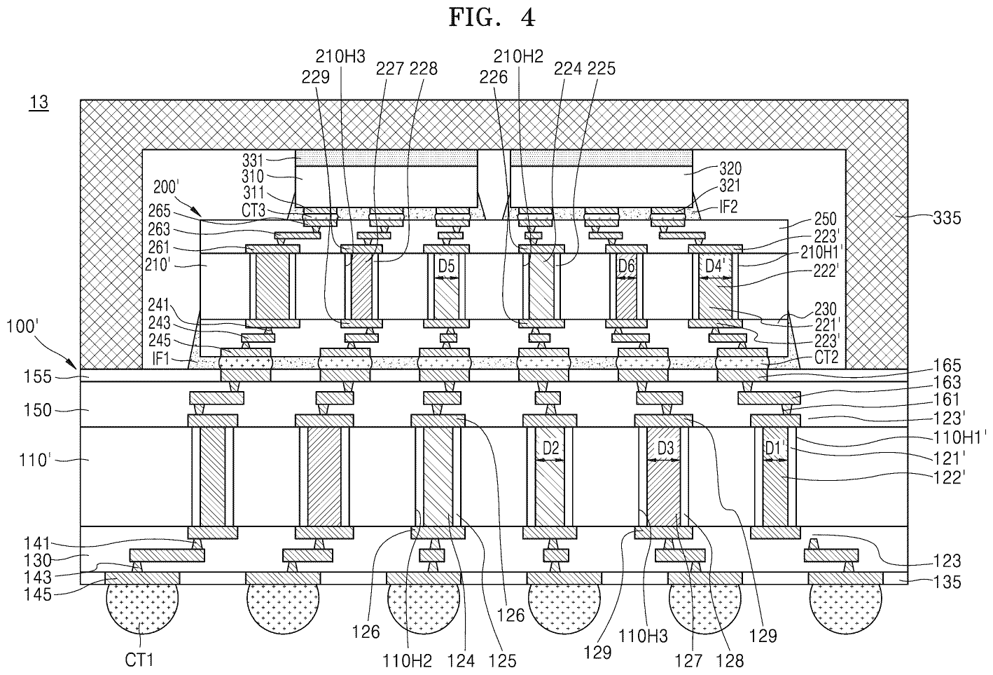

FIG. 4 is a cross-sectional view illustrating a semiconductor package 13 according to another embodiment.

Referring to FIG. 4, the semiconductor package 13 may include a package substrate 100′, a silicon-free interposer 200′, a first semiconductor chip 310, a second semiconductor chip 320, TIM layers 331, and a heat dissipation device 335.

Because the first semiconductor chip 310, the second semiconductor chip 320, the TIM layers 331, and the heat dissipation device 335 are substantially the same as those described with reference to FIGS. 1A to 1C, description thereof will not be given.

The package substrate 100′ is substantially the same as described with reference to FIG. 2. The silicon-free interposer 200′ is substantially the same as described with reference to FIG. 3.

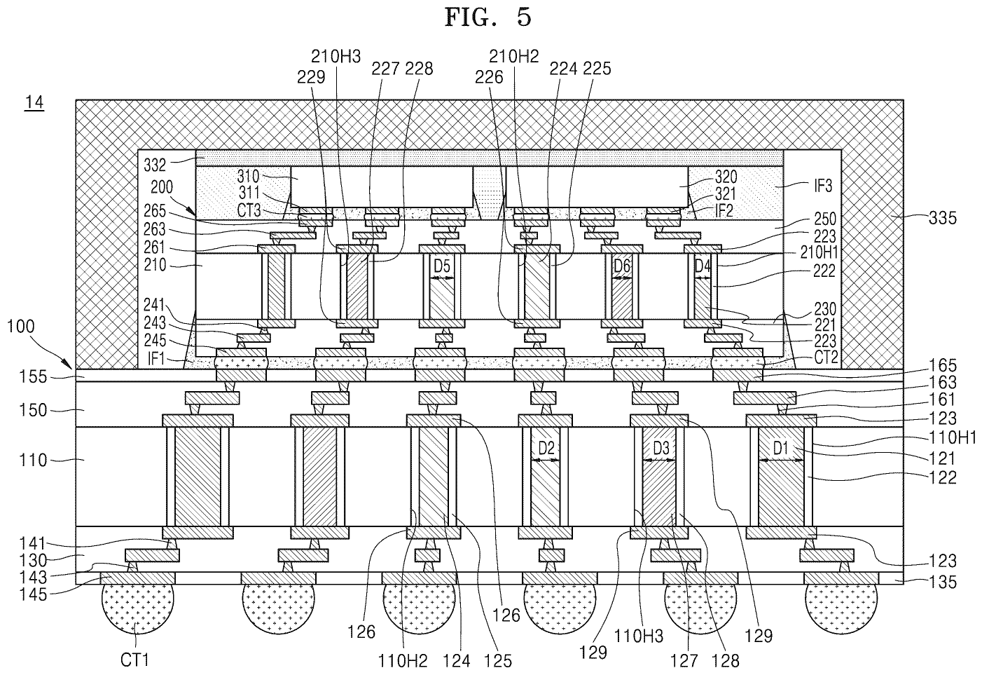

FIG. 5 is a cross-sectional view illustrating a semiconductor package 14 according to another embodiment.

Referring to FIG. 5, the semiconductor package 14 may include a package substrate 100, a silicon-free interposer 200, a first semiconductor chip 310, a second semiconductor chip 320, TIM layers 331, and a heat dissipation device 335.

Because the package substrate 100, the silicon-free interposer 200, the first semiconductor chip 310, the second semiconductor chip 320, the TIM layers 331, and the heat dissipation device 335 are substantially the same as those described with reference to FIGS. 1A to 1C, description thereof will not be given.

The semiconductor package 14 may further include a third insulating filler IF3 covering sides of each of the first and second semiconductor chips 310 and 320. The third insulating filler IF3 may include a base material layer such as epoxy resin and a filler included in the base material layer. The filler may include an organic filler or an inorganic filler. The filler may include, for example, silica. According to embodiments, the third insulating filler IF3 may include an epoxy mold compound (EMC). The semiconductor package 14 may be provided by a chip on wafer packaging process.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor package comprising:
a package substrate; and
a silicon-free interposer on the package substrate, wherein
the package substrate includes a first core layer, first core through electrodes passing through the first core layer, and second core through electrodes passing through the first core layer,
the first core through electrodes are configured to be applied with a high-speed signal,
the second core through electrodes are configured to be applied with power,
the silicon-free interposer includes a second core layer, first interposer through electrodes passing through the second core layer, and second interposer through electrodes passing through the second core layer,
the first interposer through electrodes are connected to the first core through electrodes,
the second interposer through electrodes are connected to the second core through electrodes,
diameters of the first core through electrodes are different from diameters of the second core through electrodes, and
diameters of the first interposer through electrodes are different from diameters of the second interposer through electrodes.

2. The semiconductor package of claim 1, wherein the diameters of the first core through electrodes are greater than the diameters of the second core through electrodes.

3. The semiconductor package of claim 2, wherein the diameters of the first core through electrodes are 1.5 times or less the diameters of the second core through electrodes.

4. The semiconductor package of claim 1, wherein the diameters of the first core through electrodes are less than the diameters of the second core through electrodes.

5. The semiconductor package of claim 4, wherein the diameters of the first core through electrodes are 0.5 times or more the diameters of the second core through electrodes.

6. The semiconductor package of claim 1, wherein the diameters of the first interposer through electrodes are greater than the diameters of the second interposer through electrodes.

7. The semiconductor package of claim 6, wherein the diameters of the first interposer through electrodes are 1.5 times or less the diameters of the second interposer through electrodes.

8. The semiconductor package of claim 1, wherein the diameters of the first interposer through electrodes are less than the diameters of the second interposer through electrodes.

9. The semiconductor package of claim 8, wherein the diameters of the first interposer through electrodes are 0.5 times or more the diameters of the second interposer through electrodes.

10. The semiconductor package of claim 1, wherein
the package substrate further comprises third core through electrodes passing through the first core layer,
the third core through electrodes are configured to be applied with a signal with a frequency lower than that of the high-speed signal, and
diameters of the third core through electrodes are greater than the diameters of the first core through electrodes.

11. The semiconductor package of claim 10, wherein
the silicon-free interposer further comprises third interposer through electrodes passing through the second core layer,
the third interposer through electrodes are connected to the third core through electrodes, and
the diameters of the third interposer through electrodes are greater than the diameters of the first interposer through electrodes.

12. A semiconductor package comprising:
a package substrate;
a silicon-free interposer on the package substrate; and
a first semiconductor chip and a second semiconductor chip on the silicon-free interposer, wherein
the package substrate includes a first core layer, first core through electrodes passing through the first core layer, and second core through electrodes passing through the first core layer,
the silicon-free interposer includes a second core layer, first interposer through electrodes passing through the second core layer, and second interposer through electrodes passing through the second core layer,
the first interposer through electrodes are connected to the first core through electrodes,
the second interposer through electrodes are connected to the second core through electrodes,
the semiconductor package is configured to output a high-speed signal from the first semiconductor chip and the second semiconductor chip to an outside region through the first interposer through electrodes and the first core through electrodes, and
diameters of the first interposer through electrodes are greater than diameters of the second interposer through electrodes.

13. The semiconductor package of claim 12, wherein a frequency of the high-speed signal is 1 GHz or more.

14. The semiconductor package of claim 12, wherein the diameters of the first interposer through electrodes are in a range of 30 μm to 80 μm.

15. The semiconductor package of claim 12, wherein the diameters of the second interposer through electrodes are in a range of 60 μm to 120 μm.

16. The semiconductor package of claim 12, wherein the diameters of the first core through electrodes are different from the diameters of the second core through electrodes.

17. The semiconductor package of claim 12, wherein the diameters of the first core through electrodes are greater than the diameters of the second core through electrodes.

18. The semiconductor package of claim 12, wherein the diameters of the first core through electrodes are in a range of 75 μm to 190 μm.

19. The semiconductor package of claim 12, wherein a diameter of each of the second core through electrodes is in a range of 75 μm to 125 μm.

20. A semiconductor package comprising:
a package substrate; and
a silicon-free interposer on the package substrate, wherein
the package substrate includes a first core layer, first core through electrodes passing through the first core layer, and second core through electrodes passing through the first core layer,
the first core layer has a thickness in a range of 400 μm to 2,000 μm,
diameters of the first core through electrodes are in a range of 75 μm to 190 μm,
the first core through electrodes are configured to be applied with a signal having a frequency of 1 GHz or more,
diameters of the second core through electrodes are in a range of 75 μm to 125 μm,
the silicon-free interposer includes a second core layer, first interposer through electrodes passing through the second core layer, and second interposer through electrodes passing through the second core layer,
the second core layer has a thickness in a range of 100 μm to 400 μm,
the first interposer through electrodes are connected to the first core through electrodes,
diameters of the first interposer through electrodes are in a range of 30 μm to 80 μm,
the second interposer through electrodes are connected to the second core through electrodes,
diameters of the second interposer through electrodes are in a range of 60 μm to 80 μm,
the diameters of the first core through electrodes are greater than the diameters of the second core through electrodes, and
the diameters of the first interposer through electrodes are less than the diameters of the second interposer through electrodes.
